(19) United States
(12) Patent Application Publication
(10) Pub. No.: US 2025/0107299 A1
(43) Pub. Date: Mar. 27, 2025

(54) LIGHT EMITTING DIODE PACKAGE STRUCTURE AND METHOD FOR MANUFACTURING THE SAME

(71) Applicant: TONG HSING ELECTRONIC INDUSTRIES, LTD., Taipei City (TW)

(72) Inventors: HAO-EN HUNG, Taipei City (TW); SHIH-HAN WU, Taipei City (TW); JHIH-WEI LAI, Taipei City (TW); JIAN-YU SHIH, Taipei City (TW); MING-YEN PAN, Taipei City (TW)

(21) Appl. No.: 18/522,251

(22) Filed: Nov. 29, 2023

(30) Foreign Application Priority Data
Sep. 22, 2023 (TW) 112136175

(51) Int. Cl. H01L 33/62; H01L 33/54

(52) U.S. Cl. CPC H10H 20/857; H10H 20/853; H10H 20/0362; H10H 20/0364

(57) ABSTRACT

A light emitting diode package structure and a method for manufacturing the same are provided. The LED package structure includes a substrate having a first and a second surface opposite to each other, a conductive structure including a first and a second conductive structure electrically connected with each other, a first gold layer disposed on the first conductive structure, a second gold layer disposed on the second conductive structure, an LED chip disposed on the first gold layer, and a package layer disposed on the first surface and encapsulating the first conductive structure, the first gold layer, and the LED chip. The first conductive structure is disposed on the first surface. The second conductive structure is disposed on the second surface. A thickness of the first gold layer is greater than 1 μm. The second conductive structure is completely covered by the second gold layer.

### CROSS-REFERENCE TO RELATED PATENT APPLICATION

This application claims the benefit of priority to Taiwan Patent Application No. 112136175, filed on Sep. 22, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light emitting diode (LED) package structure and a method for manufacturing the same, and more particularly to a light emitting diode package structure and a method for manufacturing the same that are applicable to high-power automotive lighting.

### BACKGROUND OF THE DISCLOSURE

In the conventional technology, a direct plated copper (DPC) ceramic substrate is a widely used substrate. The DPC ceramic substrate has a heat dissipation property of ceramics and electrical conductivity of metals, and is particularly applicable to a semiconductor package structure.

In a process of manufacturing the DPC ceramic substrate, a patterned circuit having a small gate length can be formed on the ceramic substrate by electroplating, sputtering, exposure, and development processes. In addition, a high connection force between the patterned circuit and the ceramic substrate enables the package structure to have good reliability.

However, the existing package structure still has deficiencies in design. For example, a conductive circuit is partially exposed to outside air. The exposed conductive circuit is easily oxidized or corroded by outside moisture or oxygen, thereby negatively affecting the reliability of the package structure.

Moreover, in a gold-to-gold interconnection (GGI) process, a thin gold layer is insufficient to fix an LED chip onto the conductive circuit. A weak connection force between the LED chip and the conductive circuit decreases the reliability of the package structure.

Therefore, how to enhance the reliability of the package structure and overcome the above-mentioned problems through improvements in structural design has become an important issue to be solved in the related art.

### SUMMARY OF THE DISCLOSURE

In response to the above-referenced technical inadequacies, the present disclosure provides a light emitting diode package structure and a method for manufacturing the same.

In order to solve the above-mentioned problems, one of the technical aspects adopted by the present disclosure is to provide a light emitting diode package structure. The LED package structure includes a substrate, a conductive structure, a first gold layer, a second gold layer, an LED chip, and a package layer. The substrate has a first surface and a second surface opposite to each other. The conductive structure includes a first conductive structure and a second conductive structure that are electrically connected with each other. The first conductive structure is disposed on the first surface. The second conductive structure is disposed on the second surface. The first gold layer is disposed on the first conductive structure, and a thickness of the first gold layer is greater than 1 μm. The second gold layer is disposed on the second conductive structure, and the second conductive structure is completely covered by the second gold layer. The LED chip is disposed on the first gold layer. The package layer is disposed on the first surface, and the first conductive structure, the first gold layer, and the LED chip are encapsulated by the package layer.

In one of the possible or preferred embodiments, a thickness of the second gold layer is less than 1 μm.

In one of the possible or preferred embodiments, a nickel layer is disposed between the first gold layer and the first conductive structure.

In one of the possible or preferred embodiments, a nickel layer is disposed between the second gold layer and the second conductive structure.

In one of the possible or preferred embodiments, a palladium layer is disposed between the second gold layer and the nickel layer.

In one of the possible or preferred embodiments, a conductive layer is disposed between the substrate and the conductive structure.

In one of the possible or preferred embodiments, the LED chip is connected with the first gold layer via a gold connector.

In order to solve the above-mentioned problems, another one of the technical aspects adopted by the present disclosure is to provide a method for manufacturing an LED package structure. The method includes steps of: forming at least one through hole on a substrate, in which the at least one through hole penetrates through a first surface and a second surface of the substrate that are opposite to each other; disposing a conductive structure on the substrate, in which the conductive structure includes a first conductive structure disposed on the first surface and a second conductive structure disposed on the second surface; forming a first gold layer onto the first conductive structure by an electroplating process, in which a thickness of the first gold layer is greater than 1 μm; forming a second gold layer onto the second conductive structure by a chemical plating process, in which the second conductive structure is completely covered by the second gold layer; disposing an LED chip onto the first gold layer; and disposing a package layer on the first surface to encapsulate the first conductive layer, the first gold layer, and the LED chip.

In one of the possible or preferred embodiments, the method further includes: disposing a conductive layer onto the first surface, the second surface, and a wall of the through hole by a sputtering process before disposing the conductive structure.

In one of the possible or preferred embodiments, the LED chip is disposed on the first gold layer via a gold connector by a gold-to-gold connection process after forming the second gold layer.

Therefore, in the LED package structure and the method for manufacturing the same provided by the present disclosure, by virtue of “a thickness of the first gold layer being greater than 1 μm” and “the second conductive structure being completely covered by the second gold layer,” the reliability of the LED package structure can be enhanced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of an LED package structure according to the present disclosure; and

FIG. 2 to FIG. 11 are schematic cross-sectional side views showing steps of a method for manufacturing the LED package structure according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

In order to overcome deficiencies of a conventional package structure, the present disclosure provides an LED package structure. In the LED package structure of the present disclosure, a conductive structure is not exposed to an external environment, such that the conductive structure will not be oxidized by oxygen or water vapor in the external environment. In subsequent manufacturing processes, the conductive structure will not be eroded either.

In the LED package structure of the present disclosure, an LED chip can be disposed on the conductive structure by a gold-to-gold interconnection (GGI) process. Since pure gold has outstanding electrical conductivity and thermal conductivity, the pure gold can be applied to the LED chip of a high-power automobile lighting.

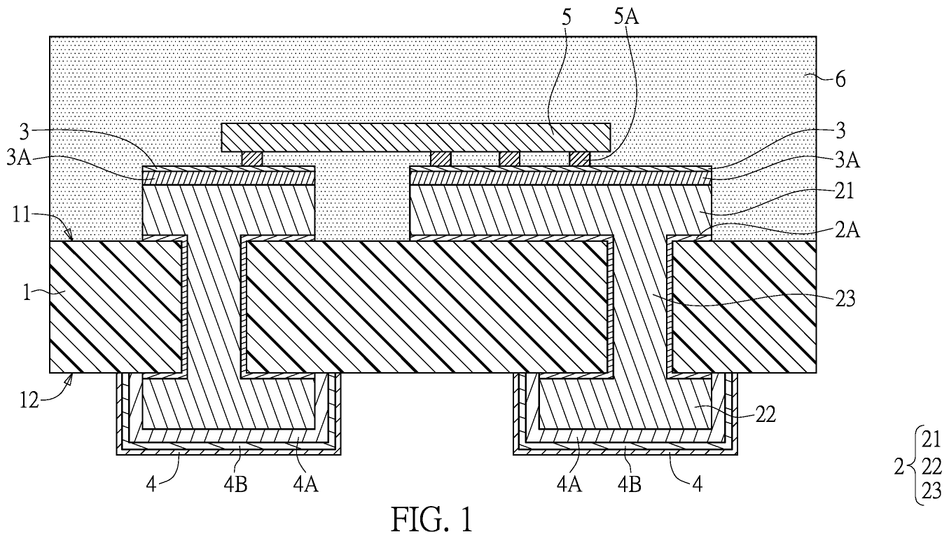

Referring to FIG. 1, the LED package structure of the present disclosure includes a substrate 1, a conductive structure 2, a first gold layer 3, a second gold layer 4, an LED chip 5, and a package layer 6.

The substrate 1 has a first surface 11 and a second surface 12 opposite to each other. The first surface 11 can be used for carrying electronic elements, such as the LED chip 5. The second surface 12 can be used for soldering or connecting with an outer circuit.

The substrate 1 can be a ceramic substrate. For example, the material of the substrate 1 can be aluminum nitride, beryllium oxide, aluminum oxide, silicon carbide, or silicon nitride, but the present disclosure is not limited thereto.

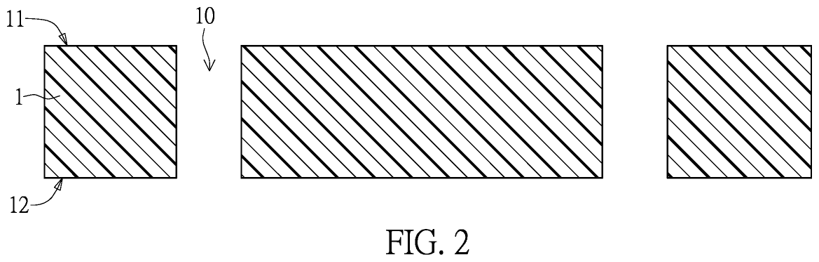

According to a designed arrangement of the conductive structure 2, at least one through hole 10 is formed on the substrate 1 (as shown in FIG. 2). The through hole 10 penetrates through the first surface 11 and the second surface 12.

Referring to FIG. 1, the conductive structure 2 is disposed on the substrate 1. In an exemplary embodiment, the conductive structure 2 is disposed in the through hole 10, and extends from the through hole 10 toward the first surface 11 and the second surface 12. In other words, the conductive structure 2 is inlaid on the substrate 1. Accordingly, the electronic elements disposed on the first surface 11 can be electrically connected with electronic elements disposed on the second surface 12 via the conductive structure 2.

For ease of illustration, the conductive structure 2 can be divided into a first conductive structure 21, a second conductive structure 22, and a third conductive structure 23. Practically, the first conductive structure 21, the second conductive structure 22, and the third conductive structure 23 are integrally formed.

A part of the conductive structure 2 extending to the first surface 11 is referred to as the first conductive structure 21. The first conductive structure 21 forms a patterned structure on the first surface 11. Another part of the conductive structure 2 extending to the second surface 12 is referred to as the second conductive structure 22. The second conductive structure 22 forms a patterned structure on the second surface 12. Yet another part of the conductive structure 2 disposed in the through hole 10 is referred to as the third conductive structure 23. Therefore, two ends of the third conductive structure 23 are respectively connected with the first conductive structure 21 and the second conductive structure 22.

The conductive structure 2 can be disposed on the substrate 1 by a direct plated copper (DPC) process or by filling a conductive paste, but the present disclosure is not limited thereto.

In order to enhance a connection force between the conductive structure 2 and the substrate 1, a conductive layer 2A can be disposed there-between. For example, the conductive layer 2A can be a titanium-copper alloy.

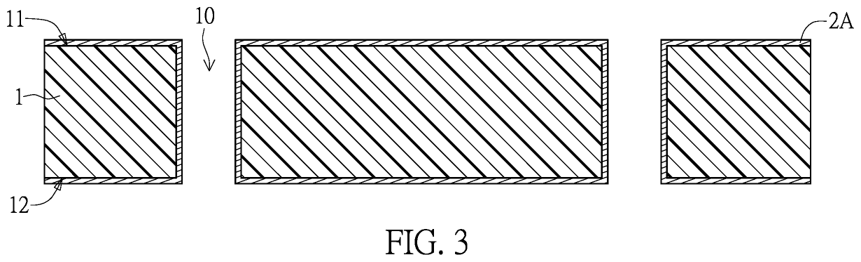

Referring to FIG. 3, the conductive layer 2A can be formed on a wall of the through hole 10, the first surface 11, the second surface 12, and a side surface of the substrate 1. It should be noted that, due to subsequent exposure and development processes, only a part of the conductive layer 2A will remain in the final product. Taking the LED package structure shown in FIG. 1 as an example, only the conductive layer 2A disposed between the conductive structure 2 and the substrate 1 remains.

Referring to FIG. 1, the first gold layer 3 is disposed on the first conductive structure 21. In the present disclosure, a thickness of the first gold layer 3 is greater than 1 μm, which enables the LED chip 5 to be disposed onto the first gold layer 3. In an exemplary embodiment, an upper surface of the first conductive structure 21 is covered by the first gold layer 3, but a side surface of the first conductive structure 21 is not covered by the first gold layer 3. However, the present disclosure is not limited thereto.

Since the thickness of the first gold layer 3 is greater than 1 μm, a connection force between the first gold layer 3 and a gold connector 5A is high. In this way, the LED chip 5 can be disposed on the first conductive structure 21 by the gold-to-gold interconnection process, and is applicable to the high-power automobile lighting. The gold connector 5A can be a gold ball, but the present disclosure is not limited thereto.

In the gold-to-gold interconnection process, if the thickness of the first gold layer 3 is less than 1 μm, the connection force between the first gold layer 3 and a gold connector 5A will be low, thereby decreasing the reliability of the LED package structure.

In order to prevent migration or diffusion of copper atoms from the first conductive structure 21 toward the first gold layer 3, a nickel layer 3A can be disposed there-between. The nickel layer 3A can act as a barrier layer. A thickness of the nickel layer 3A can range from 2.5 μm to 7.5 μm. The thickness of the first gold layer 3 can range from 1 μm to 2 μm, and is greater than 1 μm. However, the present disclosure is not limited thereto.

Referring to FIG. 1, the second gold layer 4 is disposed on the second conductive structure 22. In the present disclosure, the second conductive structure 22 is completely covered by the second gold layer 4. In other words, the second gold layer 4 is disposed on an upper surface and a side surface of the second conductive structure 22, so as to prevent the second conductive structure 22 from being exposed to the external environment or being eroded during the manufacturing processes. Accordingly, the configuration of the second gold layer 4 can not only facilitate a connection with an outer circuit but also protect the second conductive structure 22.

In an exemplary embodiment, a thickness of the second gold layer 4 can be less than 1 μm. When the thickness of the second gold layer 4 is greater than 1 μm, in addition to an increase of material costs, a melting point of a surface mount technology (SMT) also increases, which leads to incomplete solder melting and the risk of welding defects.

In order to prevent migration or diffusion of copper atoms from the second conductive structure 22 toward the second gold layer 4, a nickel layer 4A can be disposed between the second gold layer 4 and the second conductive structure 22. The nickel layer 4A can act as a barrier layer. Similarly, in order to prevent migration or diffusion of nickel atoms from the nickel layer 4A toward the second gold layer 4, a palladium layer 4B can be disposed between the second gold layer 4 and the nickel layer 4A. The palladium layer 4B can act as a barrier layer.

In an exemplary embodiment, when the nickel layer 4A and the second gold layer 4 are disposed on the second conductive structure 22, a thickness of the nickel layer 4A can range from 2.5 μm to 7.5 μm, and the thickness of the second gold layer 4 can range from 0.025 μm to 0.0625 μm. In another exemplary embodiment, when the nickel layer 4A, the palladium layer 4B, and the second gold layer 4 are disposed on the second conductive structure 22, the thickness of the nickel layer 4A can range from 2.5 μm to 7.5 μm, a thickness of the palladium layer 4B can range from 0.05 μm to 0.15 μm, and the thickness of the second gold layer 4 can range from 0.05 μm to 0.15 μm.

Referring to FIG. 1, the package layer 6 is disposed on the first surface 11. In order to prevent exposure to the external environment, the first conductive structure 21, the first gold layer 3, and the LED chip 5 are encapsulated by the package layer 6.

The package layer 6 can be formed from a molding process, but the present disclosure is not limited thereto. The material of the package layer 6 can be a silica gel.

Referring to FIG. 2 to FIG. 11, a method for manufacturing the LED package structure of the present disclosure includes the following steps S1 to S6. However, steps S1 to S6 are only used to aid in illustrating one embodiment of the present disclosure, and the present disclosure is not limited thereby.

In step S1, the at least one through hole 10 is formed on the substrate 1, and the through hole 10 penetrates through the first surface 11 and the second surface 12 (as shown in FIG. 2). In an exemplary embodiment, the substrate 1 is an aluminum nitride substrate, and the through hole 10 is formed by a laser drilling process.

As above mentioned, in order to increase the connection force between the conductive structure 2 and the substrate 1, the conductive layer 2A can be disposed on the first surface 11, the second surface 12, the side surface of the substrate 1, and the wall of the through hole 10 by a sputtering process (as shown in FIG. 3). In an exemplary embodiment, the conductive layer 2A is a titanium copper alloy.

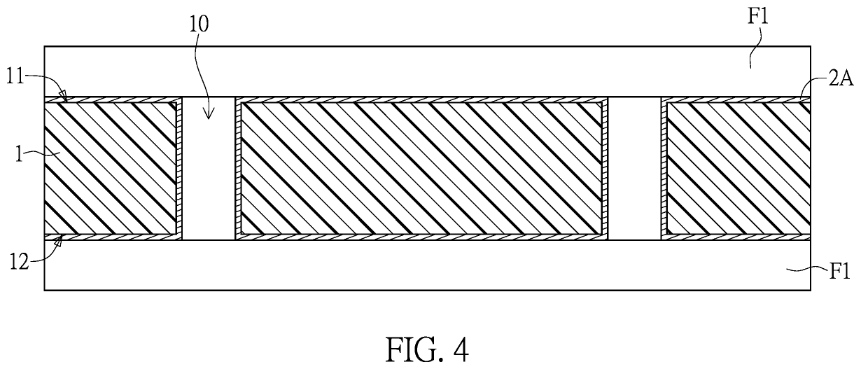

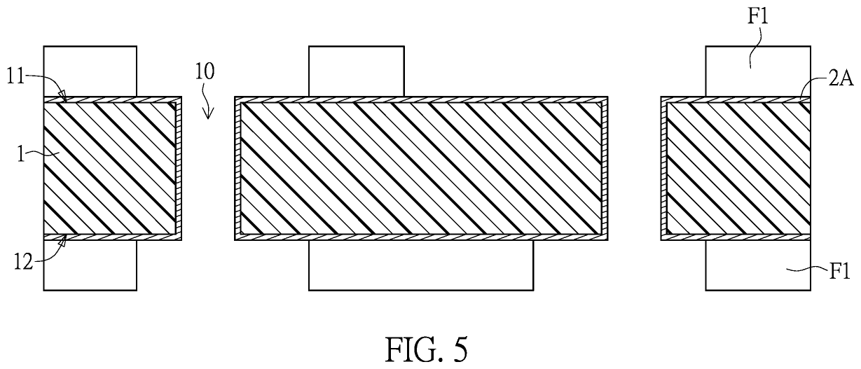

The first surface 11 and the second surface 12 are each covered by a dry film photoresist F1 (as shown in FIG. 4), and then the exposure process and the development process are implemented. According to a designed pattern of a photo mask, a part of the dry film photoresist F1 is etched. A stepped structure is formed between the remaining dry film photoresist F1 and the substrate 1 (as shown in FIG. 5).

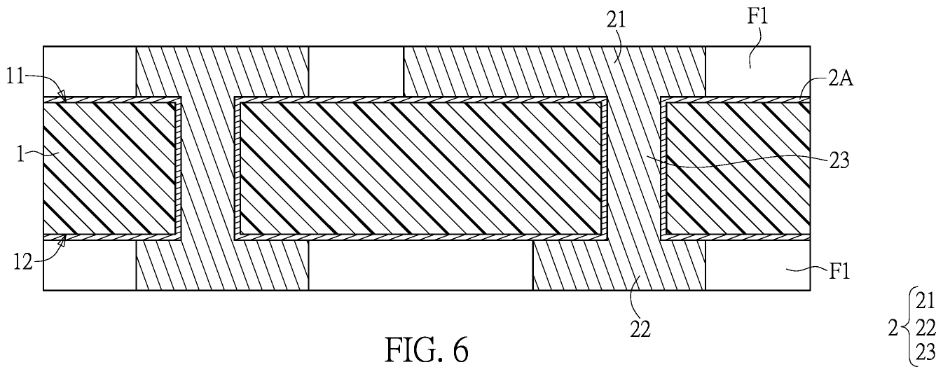

In step S2, the conductive structure 2 is disposed on the substrate 1. Specifically, the conductive structure 2 is filled in the through hole 10 and disposed on the stepped structure. The conductive structure 2 includes the first conductive structure 21 formed on the first surface 11 and the second conductive structure 22 formed on the second surface 12. In an exemplary embodiment, an upper surface of the conductive structure 2, i.e., the first conductive structure 21 and the second conductive structure 22, is flush with an upper surface of the dry film photoresist F1 (as shown in FIG. 6).

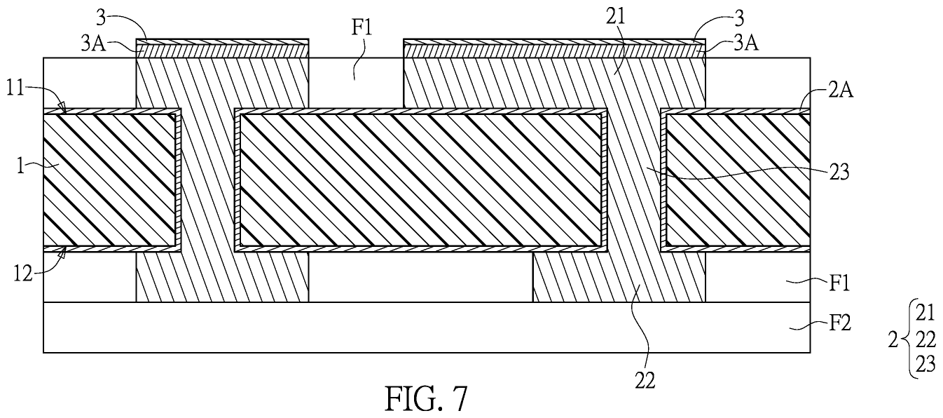

In step S3, the first gold layer 3 is formed on the first conductive structure 21 by an electroplating process. Before the electroplating process, another dry film photoresist F2 is disposed on the second conductive structure 22 (as shown in FIG. 7), so as to prevent the first gold layer 3 from forming on the second conductive structure 22.

In the electroplating process, a degreasing process is implemented. The first conductive structure 21 is washed by an acidic solution to partially remove oxide and pollution, so as to decrease a surface tension of the first conductive structure 21. After the degreasing process, the first conductive structure 21 is sequentially cleaned by hot water and deionized water.

Subsequently, a micro etching process is implemented. The first conductive structure 21 is washed by a solution of sodium persulfate (Na₂S₂O₈) and sulfuric acid to remove the oxide, and a surface of the first conductive structure 21 is roughened. The roughened first conductive structure 21 can have a higher connection force with the nickel layer 3A. After the micro etching process, the first conductive structure 21 is cleaned by deionized water.

Subsequently, an acid dipping process is implemented. The oxide on the first conductive structure 21 is removed by sulfuric acid. After the acid dipping process, the first conductive structure 21 is cleaned by deionized water.

Subsequently, a nickel pre-plating process is implemented. A thin and compact nickel layer is formed onto a surface of the first conductive structure 21, which is beneficial to the following processes.

Subsequently, a nickel electroplating process is implemented. In the nickel electroplating process, the first conductive structure 21 and a nickel metal block are immersed in an electrolyte. The first conductive structure 21 acts as a cathode, and the nickel metal block acts as an anode.

Accordingly, the nickel layer 3A is formed onto the first conductive structure 21. The thickness of the nickel layer 3A can be adjusted according to a current density and an electroplating period of the nickel electroplating process. In an exemplary embodiment, the thickness of the nickel layer 3A is 5 μm. After the nickel electroplating process, the nickel layer 3A is cleaned by deionized water.

Subsequently, a gold pre-plating process is implemented. A thin and compact gold layer is formed onto the nickel layer 3A, which is beneficial to the following processes.

Subsequently, a gold electroplating process is implemented. In the gold electroplating process, the first conductive structure 21 (cathode) and a platinum titanium steel (anode) are immersed in an electrolyte that contains potassium gold cyanide (K[Au(CN)₂).

Accordingly, the first gold layer 3 is formed onto the nickel layer 3A. The thickness of the first gold layer 3 can be adjusted according to a current density and an electroplating period of the gold electroplating process. In an exemplary embodiment, the thickness of the first gold layer 3 is greater than 1 μm, such as 1.1 μm. After the gold electroplating process, the first gold layer 3 is cleaned by deionized water.

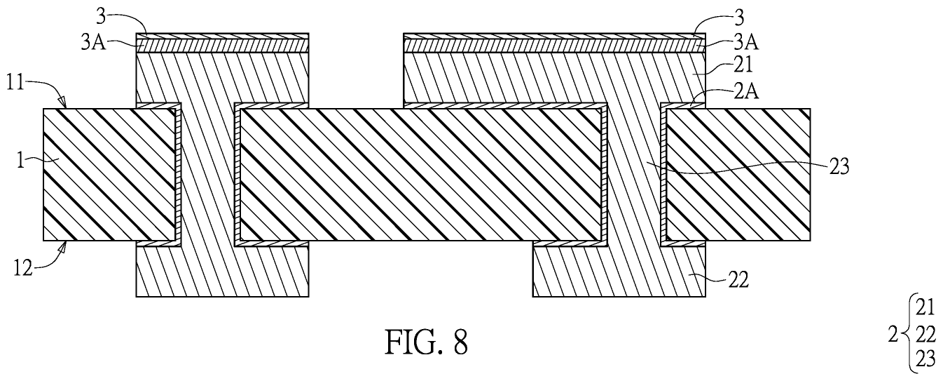

Subsequently, an etching process is implemented to remove the dry film photoresists F1, F2 and a part of the conductive layer 2A. After the etching process, only the conductive layer 2A disposed between the substrate 1 and the conductive structure 2 remains (as shown in FIG. 8).

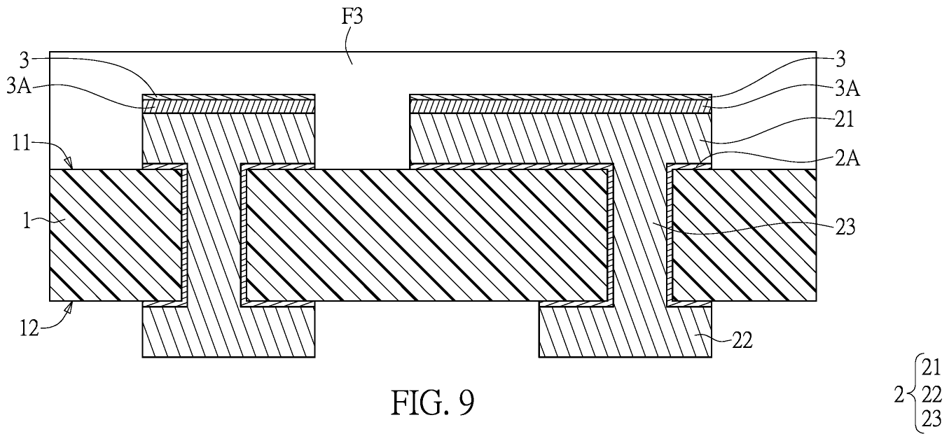

In step S4, a chemical plating process is implemented to form the second gold layer 4 onto the second conductive structure 22. Before the chemical plating process, an anti-plating tape F3 is disposed on the first conductive structure 21 (as shown in FIG. 9), so as to prevent the second gold layer 4 from forming on the first conductive structure 21.

It should be noted that a strong reducing agent is used in the chemical plating process for electron transfer (redox reactions). Through the electron transfer, a metal layer can be formed. When a surface of a plated substrate is completely covered by the metal layer, the plated substrate cannot be further oxidized. Therefore, a thickness of the metal layer formed by the chemical plating process has an upper limit. Since the chemical plating process has no regional restrictions, the plated substrate can be completely covered by the metal layer. In other words, the second conductive structure 22 can be completely covered by the metal layer.

In the chemical plating process, the degreasing process mentioned above is implemented to partially remove oxide and pollution on the second conductive structure 22. After the degreasing process, the second conductive structure 22 is sequentially cleaned by hot water and deionized water.

Subsequently, the second conductive structure 22 is subjected to the micro etching process and the acid dipping process mentioned above. After those processes, the second conductive structure 22 is cleaned by deionized water.

Subsequently, a pre-dipping process is implemented. The second conductive structure 22 is immersed into sulfuric acid, so that a surface of the second conductive structure 22 can maintain an oxygen-free state.

Subsequently, an activation process is implemented. The second conductive structure 22 under the oxygen-free state is immersed into a mixed solution containing palladium sulfate and sulfuric acid. Palladium ions in the mixed solution are attached onto the surface of the second conductive structure 22 to form the palladium metal by a chemical exchange reaction. The palladium metal can be used as a catalyst in the following processes to promote deposition of nickel metal. After the activation process, the second conductive structure 22 is cleaned by deionized water.

Subsequently, a post-dipping process is implemented. The second conductive structure 22 is immersed into a surface treatment solution to passivate the palladium metal attached on the second conductive structure 22. In an exemplary embodiment, the surface treatment solution is the model ACCEMULTA® WHE-5. After the post-dipping process, the second conductive structure 22 is cleaned by deionized water.

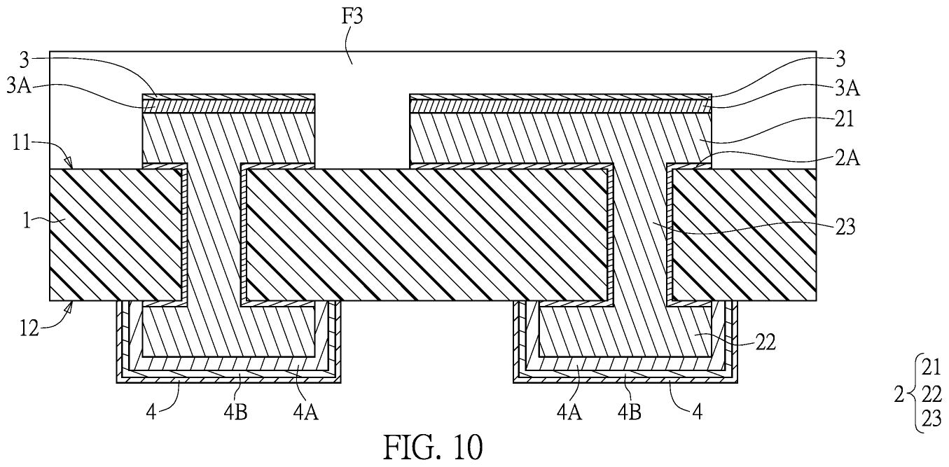

Subsequently, a nickel chemical plating process is implemented. The second conductive structure 22 is immersed into a first chemical plating solution, so as to form the nickel layer 4A (as shown in FIG. 10). The first chemical plating solution contains nickel sulfate, sodium dihydrogen hypophosphite, a complexing agent, and sodium hydroxide. Nickel sulfate can provide a nickel ion. Sodium dihydrogen hypophosphite can be used as a reducing agent to reduce the nickel ion. The complexing agent can prevent formation of nickel hydroxide. Sodium hydroxide can be used to maintain a pH value of the first chemical plating solution.

In an exemplary embodiment, the thickness of the nickel layer 4A is 5 μm. After the nickel chemical plating process, the nickel layer 4A is cleaned by deionized water.

Subsequently, a palladium chemical plating process is implemented. The nickel layer 4A is immersed into a second chemical plating solution, so as to form the palladium layer 4B (as shown in FIG. 10). The second chemical plating solution contains tetraammine dichloropalladium (Pd(NH₃)₄Cl₂) and sodium hypophosphite (NaH₂PO₂) (a reducing agent). In an exemplary embodiment, the thickness of the palladium layer 4B is 0.1 μm. After the palladium chemical plating process, the palladium layer 4B is cleaned by deionized water.

Subsequently, a gold chemical exchanging process is implemented. The palladium layer 4B is immersed into a third chemical plating solution, so as to form the second gold layer 4 (as shown in FIG. 10). The third chemical plating solution contains aurous potassium cyanide (K[Au(CN)₂]), an organic acid, and a reducing agent. In an exemplary embodiment, the thickness of the second gold layer 4 is 0.1 μm. After the gold chemical exchanging process, gold ions are recycled. Then, the second gold layer 4 is cleaned by deionized water, and the anti-plating tape covering the first surface 11 can be peeled off.

It should be noted that the palladium chemical plating process can be selectively implemented. In other words, without implementing the palladium chemical plating process, the gold chemical exchanging process can be directly implemented after the nickel chemical plating process.

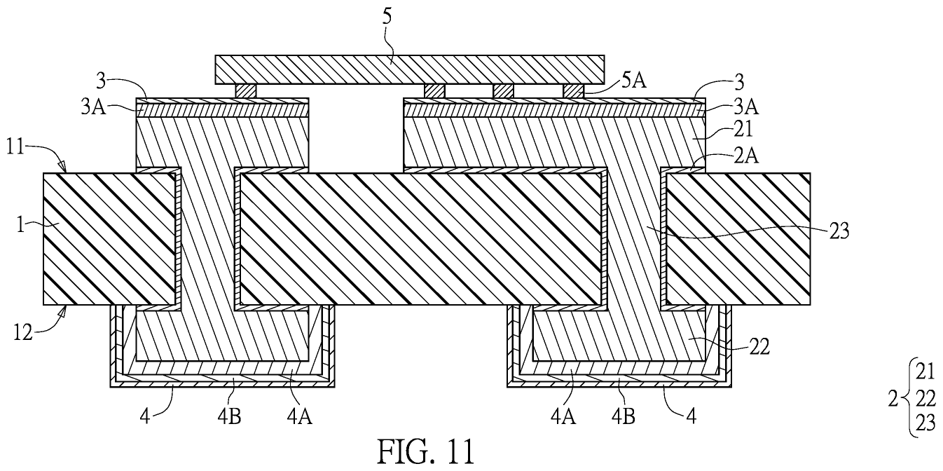

In step S5, the LED chip 5 is disposed onto the first gold layer 3 (as shown in FIG. 11). In an exemplary embodiment, through the gold-to-gold interconnection process, the LED chip 5 can be disposed onto the first gold layer 3 via the gold connector 5A, such that the LED chip 5 can be electrically connected with the first conductive structure 21.

In step S6, the package layer 6 is disposed on the first surface 11 by a molding process (as shown in FIG. 1). The first conductive structure 21, the first gold layer 3, and the LED chip 5 are encapsulated by the package layer 6, so as to be separated from the external environment.

According to steps S1 to S6, the first gold layer 3 is formed from the electroplating process, such that the thickness of the first gold layer 3 can be greater than 1 μm. In this way, the connection force between the first gold layer 3 and the gold connector 5A can be enhanced. The second gold layer 4 is formed from the chemical plating process, such that the second conductive structure 22 can be completely covered by the second gold layer 4. In this way, the second conductive structure 22 is prevented from being oxidized or eroded due to exposure to the external environment. Hence, the LED package structure of the present disclosure has good reliability.

### Beneficial Effects of the Embodiments

In conclusion, in the LED package structure and the method for manufacturing the same provided by the present disclosure, by virtue of “the thickness of the first gold layer 3 being greater than 1 μm” and “the second conductive structure 22 being completely covered by the second gold layer 4,” the reliability of the LED package structure can be enhanced.

Furthermore, the nickel layer 3A disposed between the first gold layer 3 and the first conductive structure 21 can act as a barrier layer. The barrier layer can prevent the diffusion of copper atoms from the first conductive structure 21 toward the first gold layer 3 (which may decrease the purity of the first gold layer 3). Similarly, the nickel layer 4A disposed between the second gold layer 4 and the second conductive structure 22 can act as a barrier layer. The barrier layer can prevent the diffusion of copper atoms from the second conductive structure 22 toward the second gold layer 4. Moreover, the palladium layer 4B disposed between the nickel layer 4A and the second gold layer 4 can form an interface metal compound with tin metal during a soldering process, thereby improving the connection force after the soldering process.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An LED (light emitting diode) package structure, comprising:
a substrate having a first surface and a second surface opposite to each other;
a conductive structure including a first conductive structure and a second conductive structure that are electrically connected with each other, wherein the first conductive structure is disposed on the first surface, and the second conductive structure is disposed on the second surface;
a first gold layer disposed on the first conductive structure, a thickness of the first gold layer being greater than 1 μm;
a second gold layer disposed on the second conductive structure, the second conductive structure being completely covered by the second gold layer;
an LED chip disposed on the first gold layer; and
a package layer disposed on the first surface, wherein the first conductive structure, the first gold layer, and the LED chip are encapsulated by the package layer.

2. The LED package structure according to claim 1, wherein a thickness of the second gold layer is less than 1 μm.

3. The LED package structure according to claim 1, wherein a nickel layer is disposed between the first gold layer and the first conductive structure.

4. The LED package structure according to claim 1, wherein a nickel layer is disposed between the second gold layer and the second conductive structure.

5. The LED package structure according to claim 4, wherein a palladium layer is disposed between the second gold layer and the nickel layer.

6. The LED package structure according to claim 1, wherein a conductive layer is disposed between the substrate and the conductive structure.

7. The LED package structure according to claim 1, wherein the LED chip is connected with the first gold layer via a gold connector.

8. A method for manufacturing an LED package structure, comprising:
forming at least one through hole on a substrate, wherein the at least one through hole penetrates through a first surface and a second surface of the substrate that are opposite to each other;
disposing a conductive structure on the substrate, wherein the conductive structure includes a first conductive structure disposed on the first surface and a second conductive structure disposed on the second surface;
forming a first gold layer onto the first conductive structure by an electroplating process, wherein a thickness of the first gold layer is greater than 1 μm;
forming a second gold layer onto the second conductive structure by a chemical plating process, wherein the second conductive structure is completely covered by the second gold layer;
disposing an LED chip onto the first gold layer; and
disposing a package layer on the first surface to encapsulate the first conductive layer, the first gold layer, and the LED chip.

9. The method according to claim 8, further comprising: disposing, before placement of the conductive structure, a conductive layer onto the first surface, the second surface, and a wall of the at least one through hole by a sputtering process.

10. The method according to claim 8, wherein, after formation of the second gold layer, a gold-to-gold interconnection process is performed, so that the LED chip is disposed on the first gold layer via a gold connector.
